(19) United States
(12) Patent Application Publication
(10) Pub. No.: US 2025/0187906 A1
(43) Pub. Date: Jun. 12, 2025

(54) SHELL MODULE FOR PACKAGING ELECTRONIC DEVICE AND ELECTRONIC DEVICE

(71) Applicant: AAC Microtech (Changzhou) Co., Ltd., Changzhou City (CN)

(72) Inventors: Dexing Wang, Changzhou (CN); Jinyu Zhang, Changzhou (CN); Yuanhua Tang, Changzhou (CN); Shaoping Huang, Changzhou (CN)

(21) Appl. No.: 18/793,980

(22) Filed: Aug. 5, 2024

Related U.S. Application Data
(63) Continuation of application No. PCT/CN2023/136979, filed on Dec. 7, 2023.

(51) Int. Cl. B81B 7/00; H04R 1/02; H04R 19/02

(52) U.S. Cl. CPC B81B 7/0061; H04R 1/025; H04R 19/02; B81B 2201/0257; H04R 2201/003

(57) ABSTRACT

An electronic device, and a shell module for packaging an electronic device, comprising a first shell and a second shell connected through an engagement-locking structure with a protruding inserting portion arranged on a first side of the first shell. The inserting portion is located between two engagement portions on the first side of the first shell, an inserting space is formed between two engagement portions that are on a third side of the second shell and nearest to the inserting portion, and a non-inserting space is formed between two locking portions that are on a fourth side of the second shell and nearest to the inserting portion. An orthographic projection of the inserting portion onto the inserting space completely falls within the inserting space, and an orthographic projection of the inserting portion onto the non-inserting space is at least partially located outside the non-inserting space, avoiding incorrect assembly.

### TECHNICAL FIELD

The present disclosure relates to the technical field of electronic devices, and in particular, to a shell module for packaging an electronic device and an electronic device.

### BACKGROUND

A shell module for packaging an electronic device usually includes two parts that are detachably connected, and an engagement-locking structure is usually used as a detachable connection structure. After the two parts of the shell module are correctly assembled, an engagement portion on one part of the shell module and a locking portion on the other part of the shell module are locked to achieve connection between the two parts of the shell module.

In the related art, in order to avoid incorrect assembling of the shell module, the engagement-locking structure arranged on two sides of the shell module usually is designed with a difference in spacing. However, due to a dimension of the shell module, it is difficult to achieve a significant difference in spacing, and there is quite a risk of incorrect assembling during the assembling process. Once assembled incorrectly (for example, in reverse), it is easy to cause damage to the engagement-locking structure or the shell module itself.

Therefore, it needs to provide a shell module for packaging an electronic device and an electronic device, to solve the above-mentioned problems in the related art.

### SUMMARY

The present disclosure aims at the problem of incorrect assembly of a shell module in the related art, and provides a shell module for packaging an electronic device and an electronic device. By providing a protruding inserting portion on a first side of the first shell, in an aspect, it can form an obvious identification on the appearance and distinguish the assembly direction; in another aspect, incorrect assembly won't be performed, thereby avoiding incorrect assembly during the assembling process; in still another hand, the inserting portion can serve as a positioning & guiding structure in the assembling process, assisting in the assembly of the first and second shells to improve the assembly efficiency.

To solve the above technical problem, the technical solutions of the present disclosure are as follows.

In an aspect, an embodiment of the present disclosure provides a shell module for packaging an electronic device, the shell module including: a first shell; a second shell; and an engagement-locking structure through which the first shell and the second shell are connected to each other. The engagement-locking structure includes at least one engagement portion and at least one locking portion that are engaged with each other, the at least one engagement portion is fixed to the first shell, the at least one locking portion is fixed to the second shell, the first shell includes a first side and a second side that are opposite to each other, and the second shell includes a third side and a fourth side that are opposite to each other. The engagement portion on the first side of the first shell is correspondingly engaged with the locking portion on the third side of the second shell, and the engagement portion on the second side of the first shell is correspondingly engaged with the locking portion on the fourth side of the second shell. The first side of the first shell is further provided with an inserting portion that protrudes from the first side of the first shell, the inserting portion is located between two adjacent engagement portions on the first side of the first shell, an inserting space is formed between two adjacent locking portions that are on the third side of the second shell and nearest to the inserting portion, and a non-inserting space is formed between two adjacent locking portions that are on the fourth side of the second shell and nearest to the inserting portion. An orthographic projection of the inserting portion onto the inserting space completely falls within the inserting space, and an orthographic projection of the inserting portion onto the non-inserting space is at least partially located outside the non-inserting space.

As an improvement, the first shell includes a top plate and a side plate formed by bending and extending from an edge of the top plate towards the second shell, and the top plate is spaced apart from the second shell, and the side plate abuts against a surface of the second shell. The engagement portion is fixed to an outer surface of the side plate, the locking portion is fixed to a surface of the second shell abutting against the side plate, and the locking portion is located on an outer periphery of the side plate.

As an improvement, the at least one engagement portion are detachably connected to the at least one locking portion, and the at least one engagement portion one-to-one corresponds to the at least one locking portion.

As an improvement, only one inserting portion is provided.

As an improvement, the inserting portion, the at least one engagement portion and the first shell are formed into one piece.

As an improvement, the inserting portion is a U-shaped rib including a bottom edge and two side edges that are at two ends of the bottom edge and spaced apart from each other, and the two side edges and the bottom edge together form a U-shaped structure; and after assembly is completed, the two side edges abut against two locking portions located at two sides of the inserting space.

As an improvement, the inserting portion is a cylindrical protrusion, two sides of the cylindrical protrusion abut against two locking portions located at two sides of the inserting space, and the cylindrical protrusion has a diameter not greater than a minimum width of the inserting space.

As an improvement, the inserting portion includes at least one group of bumps spaced apart in a horizontal direction, each group of bumps includes two bumps, and the two bumps abut against two locking portions located at two sides of the inserting space.

In another aspect, an embodiment of the present disclosure provides an electronic device, including: the shell module for packaging the electronic device described above; a circuit board; and at least one electronic component. The first shell and the second shell together define an accommodating space, the circuit board and the electronic component are accommodated in the accommodating space, the circuit board is connected to an external power supply through a wire, and the electronic component is mounted to the circuit board and electrically connected to the circuit board.

As an improvement, the electronic component is an MEMS device, the shell module for packaging the electronic device is provided with a sound outlet hole in communication with the outside at a position corresponding to a sound outlet of the MEMS device, and the sound generated by the MEMS device propagates outward through the sound outlet hole.

The present disclosure has the following beneficial effects.

A protruding inserting portion is provided on the first side of the first shell, to play an obvious recognition role in appearance and can distinguish the assembly direction of the first shell;

An orthographic projection of the inserting portion onto the inserting space completely falls within the inserting space, and at least a portion of the orthographic projection of the inserting portion onto the non-inserting space is located outside the non-inserting space, to prevent incorrect assembly and achieve the unique assembly;

The inserting portion can play a role in positioning and guiding during the assembling process, assisting in alignment and movement of the engagement portion and the locking portion, to improve the efficiency of assembly.

### BRIEF DESCRIPTION OF DRAWINGS

FIG. 1 is a perspective structural view of a shell module for packaging an electronic device according to Embodiment I;

FIG. 2 is an exploded structural view of the shell module for packaging the electronic device shown in FIG. 1;

FIG. 3 is a cross-sectional view along A-A of the shell module for packaging the electronic device shown in FIG. 1;

FIG. 4 is a top view of the shell module for packaging the electronic device shown in FIG. 1;

FIG. 5 is a schematic structural view of a shell module for packaging an electronic device according to Embodiment II;

FIG. 6 is a schematic structural view of a shell module for packaging an electronic device according to Embodiment III;

FIG. 7 is an exploded structural view of an electronic device according to Embodiment IV.

### DESCRIPTION OF EMBODIMENTS

The following describes the technical solutions in embodiments of the present disclosure. It should be noted that, the described embodiments are merely a few of, rather than of the embodiments of the present disclosure. Based on the embodiments in the present disclosure, all other embodiments obtained by those skilled in the art without creative efforts shall fall into a protection scope of the present disclosure.

### Embodiment I

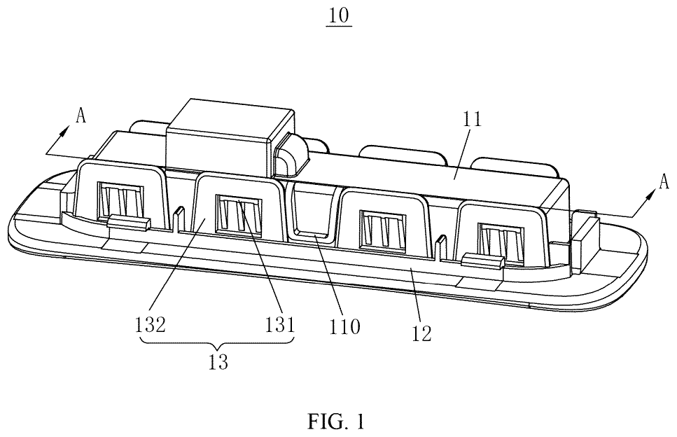

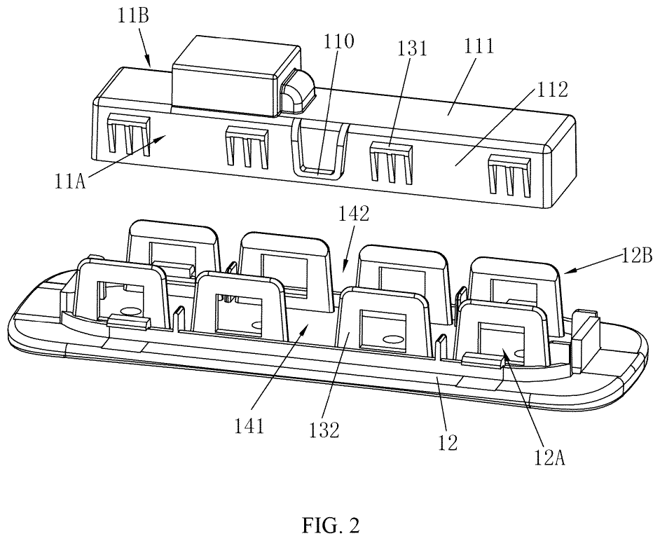

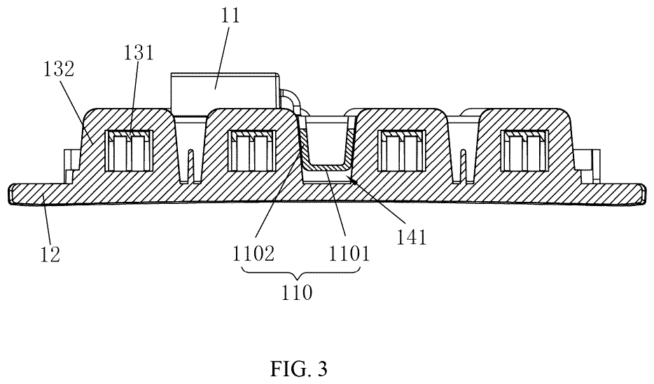

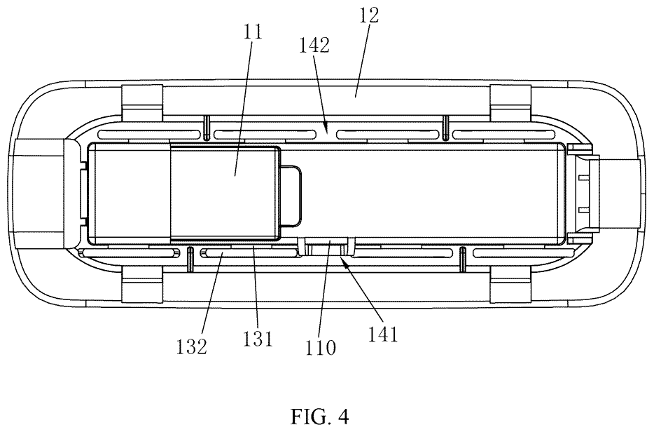

Referring to FIG. 1 to FIG. 4, an embodiment of the present disclosure provide a shell module 10 for packaging an electronic device, including a first shell 11, a second shell 12 and an engagement-locking structure 13. The first shell 11 and the second shell 12 are connected together by means of the engagement-locking structure 13. The first shell 11 and the second shell 12 together define an accommodating space, which is configured to accommodate and install other electronic components.

In this embodiment, the first shell 11 includes a top plate 111 and a side plate 112 formed by bending and extending from an edge of the top plate 111 towards the second shell 12. The top plate 111 is spaced apart from the second shell 12, and the side plate 112 abuts against a surface of the second shell 12.

The engagement-locking structure 13 includes an engagement portion 131 and a locking portion 132 that are engaged with each other, and the engagement portion 131 and the locking portion 132 are detachably connected to each other. The engagement portion 131 is fixed to the first shell 11, the locking portion 132 is fixed to the second shell 12. The engagement portion 131 one-to-one corresponds to the locking portion 132. As an improvement, the engagement portion 131 and the first shell 11 are formed into one piece to ensure structural stability.

In this embodiment, the engagement-locking structure 13 is a buckle structure, a male connector of the buckle structure is the engagement portion, and a female connector of the buckle structure is the locking portion. The engagement-locking structure 13 may also be in other detachable engagement-locking forms, such as an inserting column & a slot, a latch & a lock, etc.

The engagement portion 131 is fixed to an outer surface of the side plate 112. The locking portion 132 is fixed to a surface of the second shell 12 abutting against the side plate 112, and the locking portion 132 is located at an outer periphery of the side plate 112.

In an electronic device, the shell module 10 for packaging the electronic device generally also serves to fix internal electronic components. Due to the asymmetry in the distribution positions of the electronic components, the shape of the shell module 10 for packaging the electronic device generally also has asymmetry, therefore the assembling direction needs to be distinguished during assembly, and the internal electronic components may be damaged in a case of reverse assembly. Therefore, the directions of the first shell 11 and the second shell 12 need to be distinguished, to ensure the correctness of the assembly direction.

In order to describe the assembly direction of the shell module 10 for packaging the electronic device more clearly, the directions of the first shell 11 and the second shell 12 are defined as follows: the first shell 11 includes a first side 11A and a second side 11B arranged opposite to each other, and the second shell 12 includes a third side 12A and a fourth side 12B arranged opposite to each other. Each of the first side 11A and the second side 11B of the first shell 11 is provided with the engagement portion 131, and each of the third side 12A and the fourth side 12B of the second shell 12 is provided with the locking portion 132. The number of the engaging portions 131 on the first side 11A is equal to the number of the engaging portions 131 on the second side 11B of the first shell 11.

The correct assembling process is as follows: the engagement portions 131 on the first side 11A of the first shell 11 are one-to-one correspondingly locked to the locking portions 132 on the third side 12A of the second shell 12, and the engagement portions 131 on the second side 11B of the first shell 11 are one-to-one correspondingly locked to the locking portions 132 on the fourth side 12B of the second shell 12.

In order to achieve a better assembly effect, the first side 11A of the first shell 11 is further provided with a protruding inserting portion 110. The inserting portion 110 plays a role in distinguishing from an appearance, such that one can visually distinguish the first side 11A from the second side 11B of the first shell 11. In this way, an orientation of the first shell 11 can be quickly determined during a material taking process, thereby ensuring that the assembly direction of the first shell 11 is correct. As an improvement, the inserting portion 110 and the first shell 11 are formed into one piece.

In an example, only one inserting portion 110 is provided. However, more than one inserting portion 110 may also be provided according to actual requirements, which will not be limited in the present disclosure.

The inserting portion 110 is located between any two of the engagement portions 131 on the first side 11A of the first shell 11. Two of the locking portions 132 located on the third side 12A of the second shell 12 that are nearest to the inserting portion 110 are spaced apart to form an inserting space 141, and two of the locking portions 132 located on the fourth side 12B of the second shell 12 that are nearest to the inserting portion 110 are spaced apart to form a non-inserting space 142. An orthographic projection of the inserting portion 110 onto the inserting space 141 completely falls within the inserting space 141, and at least art of an orthographic projection of the inserting portion 110 onto the non-inserting space 142 is located outside the non-inserting space 142.

In the assembling process, when reverse assembly is performed, that is, when the first side 11A of the first shell 11 is trying to assembly to the fourth side 12B of the second shell 12, the inserting portion 110 cannot be smoothly inserted between two adjacent locking portions 132 on the fourth side 12B of the second shell 12; when correct assembly is performed, that is, when the first side 11A of the first shell 11 is trying to be assembled to the third side 12A of the second shell 12, the inserting portion 110 can be smoothly inserted between two adjacent locking portions 132 on the third side 12A of the second shell 12. The inserting portion 110 ensures an unique assembly direction, thereby avoiding incorrect assembly during the assembling process.

In this embodiment, in an example, the inserting portion 110 is a U-shaped rib, including a bottom edge 1101 and two side edges 1102, the two side edges 1102 are at two ends of the bottom edge 1101 and spaced apart from each other. The two side edges 1102 and the bottom edge 1101 form a U-shaped structure. After the assembly is completed, the two side edges 1102 respectively abut against the two locking portions 132 at two sides of the inserting space 141.

The two side edges 1102 can play a guiding role in the assembling process, allowing the first shell 11 and the second shell 12 to move along extending directions of the side edges 1102, thereby maintaining stability in the assembling process.

### Embodiment II

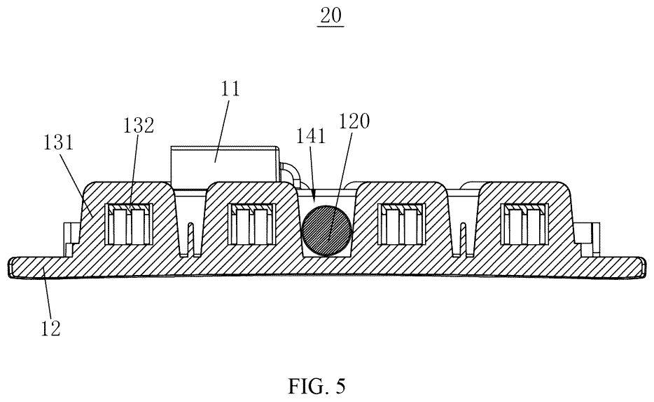

Referring to FIG. 5, an embodiment provides another shell module 20 for packaging an electronic device. Compared with Embodiment I, Embodiment II only has differences in terms of the structure of an inserting portion.

In this embodiment, the inserting portion 120 is a cylindrical protrusion. Two sides of the cylindrical protrusion respectively abut against two locking portions 132 located at two sides of the inserting space 141. The cylindrical protrusion has a diameter not greater than a minimum width of the inserting space 141, to ensure that the inserting portion 120 can be smoothly inserted at a position between the two locking portions 132.

### Embodiment III

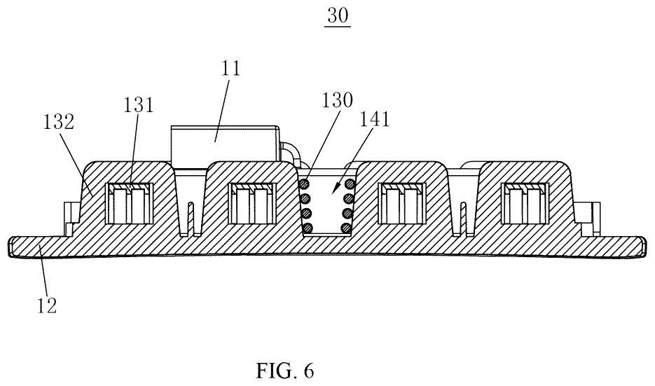

Referring to FIG. 6, an embodiment provides another shell module 30 for packaging an electronic device. Compared with Embodiment I, embodiment III only has differences in terms of the structure of an inserting portion.

In this embodiment, the inserting portion 130 includes at least one group of bumps spaced apart in a horizontal direction. Each group of bumps includes two bumps, and the two bumps respectively abut against two locking portions 132 located at two sides of the inserting space 141.

On the basis of Embodiment I, this embodiment omits the structure of the bottom edge 1101, and simplifies the continuous side edge 1102 by providing multiple spaced bumps, thereby making the structure more simplified.

### Embodiment IV

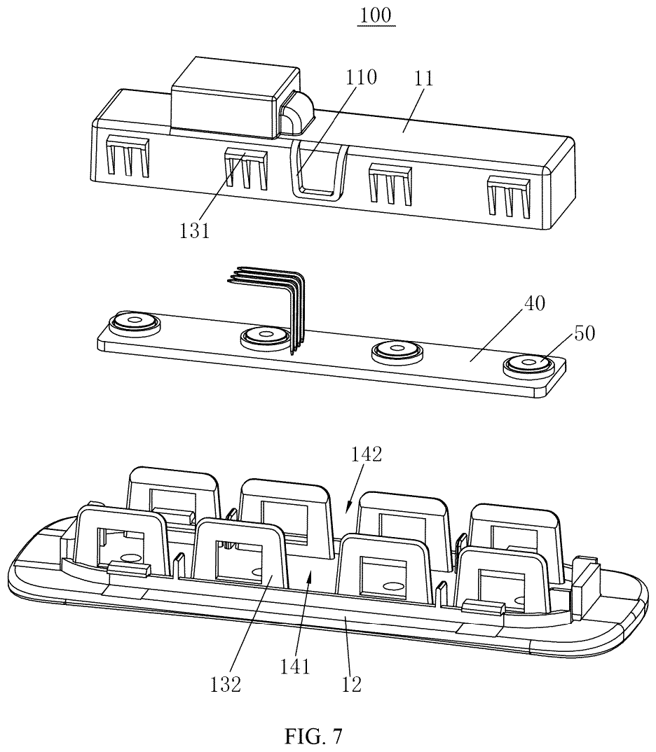

Referring to FIG. 7, an embodiment provides an electronic device 100, including the shell module 10 for packaging the electronic device according to Embodiment I, a circuit board 40, and at least one electronic component 50. The first shell 11 and the second shell 12 together define an accommodating space, and the circuit board 40 and the electronic component 50 are both accommodated in the accommodating space. The circuit board 40 is connected to an external power supply through a wire. The electronic component 50 is mounted to the circuit board 40 and electrically connected to the circuit board 40.

In this embodiment, the electronic component 50 may be an MEMS device. The shell module 10 for packaging the electronic device is provided with a sound outlet hole in communication with the outside at a position corresponding to a sound outlet of the MEMS device, and the sound generated by the MEMS device propagates outward through the sound outlet hole.

It should be noted that the shell module 10 for packaging an electronic device in this embodiment may be replaced with the shell module 20 for packaging an electronic device in Embodiment II or the shell module 30 for packaging an electronic device in Embodiment III, which will not affect the expression of this embodiment.

The above description merely illustrates some embodiments of the present disclosure, and it should be noted that those skilled in the art can also make improvements without departing from a concept of the present disclosure, but these all improvements shall fall into a protection scope of the present disclosure.

What is claimed is:

1. A shell module for packaging an electronic device, the shell module comprising:
a first shell;
a second shell; and
an engagement-locking structure through which the first shell and the second shell are connected to each other,
wherein the engagement-locking structure comprises at least one engagement portion and at least one locking portion that are engaged with each other, the at least one engagement portion is fixed to the first shell, the at least one locking portion is fixed to the second shell, the first shell comprises a first side and a second side that are opposite to each other, and the second shell comprises a third side and a fourth side that are opposite to each other,
wherein the engagement portion on the first side of the first shell is correspondingly engaged with the locking portion on the third side of the second shell, and the engagement portion on the second side of the first shell is correspondingly engaged with the locking portion on the fourth side of the second shell,
wherein the first side of the first shell is further provided with an inserting portion that protrudes from the first side of the first shell, the inserting portion is located between two adjacent engagement portions on the first side of the first shell, an inserting space is formed between two adjacent locking portions that are on the third side of the second shell and nearest to the inserting portion, and a non-inserting space is formed between two adjacent locking portions that are on the fourth side of the second shell and nearest to the inserting portion, and
wherein an orthographic projection of the inserting portion onto the inserting space completely falls within the inserting space, and an orthographic projection of the inserting portion onto the non-inserting space is at least partially located outside the non-inserting space.

2. The shell module for packaging an electronic device as described in claim 1,
wherein the first shell comprises a top plate and a side plate formed by bending and extending from an edge of the top plate towards the second shell, and the top plate is spaced apart from the second shell, and the side plate abuts against a surface of the second shell, and
wherein the engagement portion is fixed to an outer surface of the side plate, the locking portion is fixed to a surface of the second shell abutting against the side plate, and the locking portion is located on an outer periphery of the side plate.

3. The shell module for packaging an electronic device as described in claim 1,
wherein the at least one engagement portion are detachably connected to the at least one locking portion, and the at least one engagement portion one-to-one corresponds to the at least one locking portion.

4. The shell module for packaging an electronic device as described in claim 1, wherein only one inserting portion is provided.

5. The shell module for packaging an electronic device as described in claim 1,
wherein the inserting portion, the at least one engagement portion and the first shell are formed into one piece.

6. The shell module for packaging an electronic device as described in claim 1,
wherein the inserting portion is a U-shaped rib comprising a bottom edge and two side edges that are at two ends of the bottom edge and spaced apart from each other, and the two side edges and the bottom edge together form a U-shaped structure; and wherein after assembly is completed, the two side edges abut against two locking portions located at two sides of the inserting space.

7. The shell module for packaging an electronic device as described in claim 1,
wherein the inserting portion is a cylindrical protrusion, two sides of the cylindrical protrusion abut against two locking portions located at two sides of the inserting space, and the cylindrical protrusion has a diameter not greater than a minimum width of the inserting space.

8. The shell module for packaging an electronic device as described in claim 1,
wherein the inserting portion comprises at least one group of bumps spaced apart in a horizontal direction, each group of bumps comprises two bumps, and the two bumps abut against two locking portions located at two sides of the inserting space.

9. An electronic device, comprising:
the shell module for packaging the electronic device as claimed in any one of claim 1;
a circuit board; and
at least one electronic component,
wherein the first shell and the second shell together define an accommodating space, the circuit board and the electronic component are accommodated in the accommodating space, the circuit board is connected to an external power supply through a wire, and the electronic component is mounted to the circuit board and electrically connected to the circuit board.

10. The electronic device as described in claim 9,
wherein the electronic component is an MEMS device, the shell module for packaging the electronic device is provided with a sound outlet hole in communication with the outside at a position corresponding to a sound outlet of the MEMS device, and the sound generated by the MEMS device propagates outward through the sound outlet hole.
